(19) United States
(12) Patent Application Publication
(10) Pub. No.: US 2022/0163399 A1
(43) Pub. Date: May 26, 2022

(54) ATTACHMENT STRUCTURE FOR TEMPERATURE SENSOR

(71) Applicant: FUJIKIN INCORPORATED, Osaka-shi (JP)

(72) Inventors: Hidehiro Doya, Osaka-shi (JP); Takayuki Suzuki, Osaka-shi (JP); Yusuke Shibata, Osaka-shi (JP)

(73) Assignee: FUJIKIN INCORPORATED, Osaka-shi (JP)

(21) Appl. No.: 17/440,460

(22) PCT Filed: Mar. 23, 2020
(86) PCT No.: PCT/JP2020/012572

§ 371 Date: Sep. 17, 2021

(30) Foreign Application Priority Data
Mar. 25, 2019 (JP) 2019-075170

(51) Int. Cl. G01K 1/14

(52) U.S. Cl. CPC G01K 1/14; F16K 37/005

(57) ABSTRACT

Provided is a temperature sensor attachment structure capable of reliably fixing a temperature sensor and being retrofitted to a standard component. Provided is an attachment structure of a temperature sensor to be attached to flow path blocks or a fluid control device of a fluid control apparatus including the plurality of flow path blocks each of which includes a fluid flow path therein and on at least one surface of which has an opening portion of the fluid flow path, and the fluid control device placed on the flow path blocks. The attachment structure includes a rectangular temperature sensor attachment piece, and a pair of clamping pieces extending from opposite sides of the attachment piece facing each other.

### TECHNICAL FIELD

The present invention relates to a fluid control apparatus used in a semiconductor manufacturing apparatus or the like, and particularly, to a temperature sensor attachment structure to be attached to a fluid control apparatus with a heating device.

### BACKGROUND ART

A fluid control apparatus used in a semiconductor manufacturing apparatus is configured such that various fluid control devices are arranged in a plurality of rows and flow paths of the fluid control devices in adjacent rows are connected to each other by a device connecting unit at predetermined positions, but in recent years, in this type of fluid control apparatus, integration in which a mass flow controller, an opening/closing valve, and the like are connected without using a tube has been advanced.

In this type of integrated fluid control apparatus, a heating device may be required for purposes of preventing dew condensation, preventing re-liquefaction when a fluid that is liquid at a normal temperature is gasified and flows, and the like. In such a fluid control apparatus to which a heating device is attached, ribbon-shaped planar heaters are disposed on both sides of at least one line, and these planar heaters are held on corresponding coupling members by a plurality of metal clips (PTL 1).

In the fluid control apparatus in which the heating device is disposed, a temperature sensor for temperature adjustment (thermocouple, or the like) is attached, so that insufficient heating or excessive heating is adjusted.

In the related art, a temperature sensor for temperature adjustment is operated by being attached, with an adhesive tape, to a flow path block on which the fluid control device is placed, in particular, to a flow path block on a downstream side of the mass flow controller that controls a flow rate.

### CITATION LIST

### Patent Literature

PTL 1: JP-A-2002-267100

### SUMMARY OF INVENTION

### Technical Problem

However, in the case of attachment with the adhesive tape, there is a problem in that the temperature sensor is not completely fixed and is detached by an external stress, and the temperature control cannot be performed. In order to firmly attach the temperature sensor, it is conceivable to provide a screw hole or the like for attaching and fixing the temperature sensor to the flow path block, but there is a problem in terms of standardization in which special measures are taken, cost increases, and versatility decreases.

The invention is made in view of the above points, and an object thereof is to provide a temperature sensor attachment structure capable of reliably fixing a temperature sensor and capable of being retrofitted to a standard component.

### Solution to Problem

A temperature sensor attachment structure according to the invention, which is made to solve the above problems, is to be attached to flow path blocks of an integrated fluid control apparatus including the plurality of flow path blocks each of which includes a fluid flow path therein and at least one surface of which has an opening portion of the fluid flow path, and a fluid control device placed on the flow path blocks. The temperature sensor attachment structure includes a rectangular temperature sensor attachment piece, and a pair of clamping pieces extending from opposite sides of the attachment piece facing each other.

In this temperature sensor attachment structure, when the flow path block is sandwiched by the pair of the opposite sides extending from the attachment piece to which the temperature sensor is attached and an upward pulling force is applied, the attachment structure abuts against the fluid control device placed on the flow path blocks, thereby effectively preventing the temperature sensor from being pulled upward.

In this case, a stopper piece extends inward from a lower side of at least one of the temperature sensor attachment piece and the clamping pieces. Accordingly, it is possible to cope with the case where the temperature sensor is attached to an upper block (fluid control device (flow rate controller, automatic opening/closing valve, or the like)) placed on the flow path block (lower block).

In these cases, bending portions that are bent inward can be provided on end sides of the clamping pieces on sides opposite to a temperature sensor attachment piece side. The bending portions are stuck in a surface of the flow path block opposite to the temperature sensor attachment piece, so that even when a horizontal stress is applied to the attachment structure, the attachment structure can be prevented from being pulled out.

Further, in these cases, a surface of the temperature sensor attachment piece can be covered with a ribbon-shaped heating unit. By setting an attachment position of the temperature sensor to an attachment position of the heating unit, the temperature sensor is more firmly prevented from being pulled out in a horizontal direction.

### Advantageous Effect

According to the invention, it is possible to provide a temperature sensor attachment structure capable of reliably fixing a temperature sensor to a flow rate control device, particularly an integrated flow rate control device, and capable of being retrofitted to a standard component.

### BRIEF DESCRIPTION OF DRAWINGS

FIG. 1 is a perspective view showing an integrated flow rate control device before a temperature sensor attachment structure according to an embodiment of the invention is attached.

FIG. 2 is a perspective view showing the integrated flow rate control device after the same temperature sensor attachment structure is attached.

FIG. 3 is a perspective view of the same temperature sensor attachment structure, in which (a) shows a first embodiment, (b) shows an example in which a bent portion is simply bent at a right angle, and (c) shows a second embodiment.

FIG. 4 is a perspective view showing a state in which the same temperature sensor attachment structure according to the second embodiment is attached to an upper block.

FIG. 5 shows the same temperature sensor attachment structure according to a third embodiment, in which (a) is a perspective view, (b) is a plan view, (c) is a plan view for illustrating a process of attaching the temperature sensor attachment structure to a block, and (d) is a plan view showing a state in which the temperature sensor attachment structure is attached to the block.

### DESCRIPTION OF EMBODIMENTS

Hereinafter, embodiments of the invention will be described in detail with reference to the drawings. The following embodiments are merely preferred examples in nature, and are not intended to limit the scope, applications, or use of the invention.

### First Embodiment

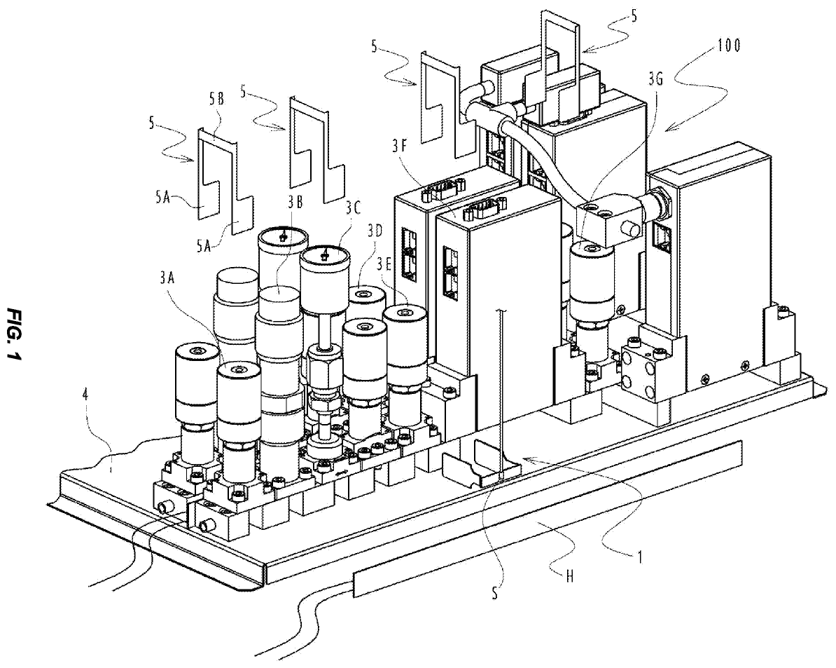

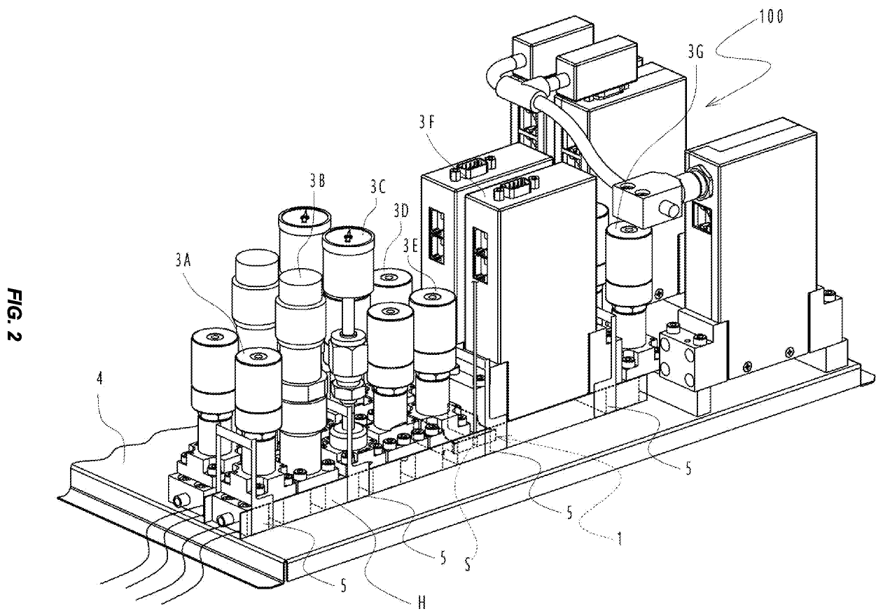

FIGS. 1 to 3 show a temperature sensor attachment structure according to a first embodiment of the invention.

### [Fluid Control Apparatus]

A fluid control apparatus 100 shown in FIG. 1 includes a plurality of fluid control devices 3A to 3G on an upper stage, a plurality of flow path blocks 2 each of which has a fluid flow path in an inner portion and on which the plurality of fluid control devices 3A to 3G are placed on a lower stage, a support member 4 that supports the plurality of flow path blocks 2, a heating unit H that heats surfaces of the flow path blocks 2 and the fluid control devices 3A to 3G, a temperature sensor S that measures a temperature of the surfaces of the flow path blocks 2 or the fluid control devices 3A to 3G, and a temperature sensor attachment structure 1 for attaching the temperature sensor S to the flow path blocks 2 or the fluid control devices 3A to 3G.

The flow path blocks 2 and the fluid control devices 3A to 3G are set in one line, and two lines are shown in the drawing, but the number of lines is not limited thereto, and the number of lines can be freely determined from one line to a plurality of lines according to an apparatus.

### [Heating Unit]

The heating unit H is in contact with side surfaces of the flow path blocks 2 to perform heating and heats the flow path to a predetermined temperature, and heats a gas (for example, hydrogen fluoride) flowing in via an inlet pipe to prevent liquefaction of the gas liquefied at a normal temperature.

The heating unit H in contact with the side surfaces of the flow path blocks 2 is sandwiched and fixed by clips 5. The illustrated example shows that a height dimension of the heating unit H constituted by a planar heater is adjusted to a height dimension of the flow path block 2 (lower block), and the heating unit H may have a height that covers lower sides of the fluid control devices 3A to 3G (upper block).

The clip 5 is formed by performing a bending process on a thin plate material such that narrow pressing portions 5A extend in a vertical direction and are parallel to the side surfaces of the flow path blocks 2 and the fluid control devices 3A to 3G. A coupling portion 5B extends along a lateral direction of the gas line and couples the pair of narrow pressing portions 5A.

As shown in FIGS. 1 and 2, the clips 5 are configured such that the temperature sensor attachment structure 1 and the heating unit H are attached to the flow path block 2 and the fluid control devices 3A to 3G and are fixed by being sandwiched. For example, a silicone sponge heat insulating material may be provided to cover a surface of the heating unit H and upper surfaces of block portions of the fluid control devices 3A to 3G, and the material may also be fixed by the clips 5.

### [Temperature Sensor]

The temperature sensor S attached to the temperature sensor attachment structure 1 transmits a measured temperature of the flow path blocks 2 or the fluid control devices 3A to 3G to a control device (not shown) that controls the fluid control devices 3A to 3G, and the control device can control the fluid control devices 3A to 3G according to the measured temperature, and when the temperature deviates from a predetermined temperature threshold, the control device can issue an instruction to perform an emergency stop on the devices. The temperature sensor S is not particularly limited, and a thermocouple is used in the present embodiment. As the temperature sensor S, a thermostat may be used.

The temperature sensor attachment structure 1 is attached to the flow path blocks 2 or the fluid control devices 3 described above, and includes a rectangular temperature sensor attachment piece 10 and a pair of clamping pieces 11 extending from opposite sides 10a, 10a of the attachment piece 10 facing each other.

In the present embodiment, the temperature sensor attachment piece 10 and the clamping pieces 11, 11 are produced by performing the bending process on a single sheet metal. By performing the bending process on the sheet metal, the clamping pieces 11, 11 have elasticity that causes the clamping pieces 11, 11 to return to an original position even when the clamping pieces 11, 11 are expanded. An interval L between the clamping pieces 11, 11 (a width dimension of the temperature sensor attachment piece 10) is set to be substantially the same dimension as a width dimension of the flow path block 2 or the fluid control device 3 to be attached. In general, this width dimension, particularly the width dimension of the flow path block 2, is standardized in an integrated fluid control apparatus, and it is not necessary to prepare many kinds thereof.

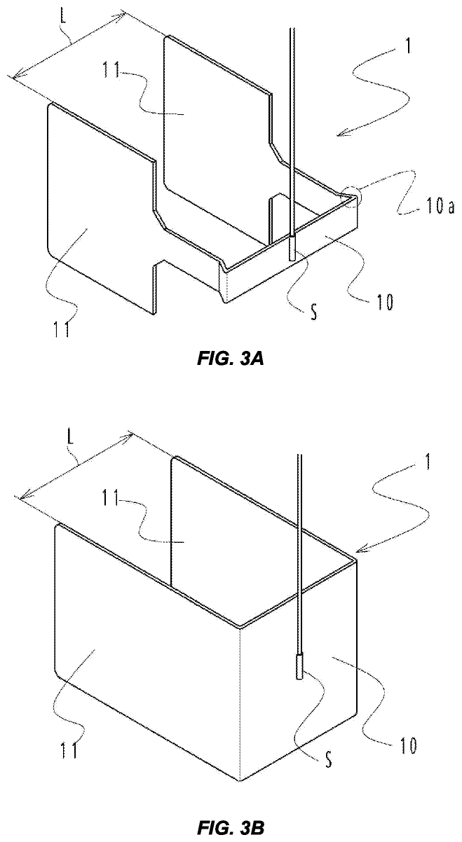

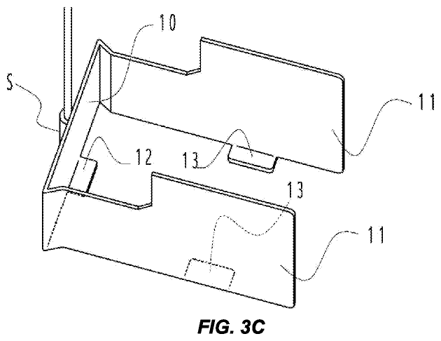

Further, portions of the opposite sides 10a of the attachment piece 10 facing each other may be bent at a right angle to form the clamping pieces 11, 11 as shown in FIG. 3 (b), but in the present embodiment, as shown in FIG. 3 (a), the width dimension of the attachment piece 10 is made slightly longer than the interval L between the clamping pieces 11, 11, inner sides of the opposite sides 10a are bent at an acute angle, and the clamping pieces 11, 11 are further bent so as to be orthogonal to the attachment piece 10, thereby forming the clamping pieces 11, 11. As a result, it is possible to improve the elasticity by the bending process, and to reliably hold the flow path block 2 by the clamping pieces 11, 11. Even when an upward stress (pull-out force) is applied to the temperature sensor S, upper sides of the clamping pieces 11, 11 abut against a bottom surface of the fluid control device 3 placed on the adjacent flow path blocks 2, so that the temperature sensor S can be prevented from being pulled out of the flow path block.

Further, as shown in FIG. 3(b), dimensions of the attachment piece 10 and the clamping pieces 11, 11 in a height direction may be the same, and as shown in FIG. 3(a), the dimension of the attachment piece 10 in the height direction may be shorter than the dimension of the clamping pieces 11, 11 in the height direction.

### Second Embodiment

Further, as shown in FIG. 3(c), the temperature sensor attachment structure 1 can be configured such that stopper pieces 12, 13 extend inward from a lower side of at least one of the temperature sensor attachment piece 10 and the clamping pieces 11, 11. It is preferable that the stopper pieces 12, 13 are also cut out from one sheet metal and formed by the bending process.

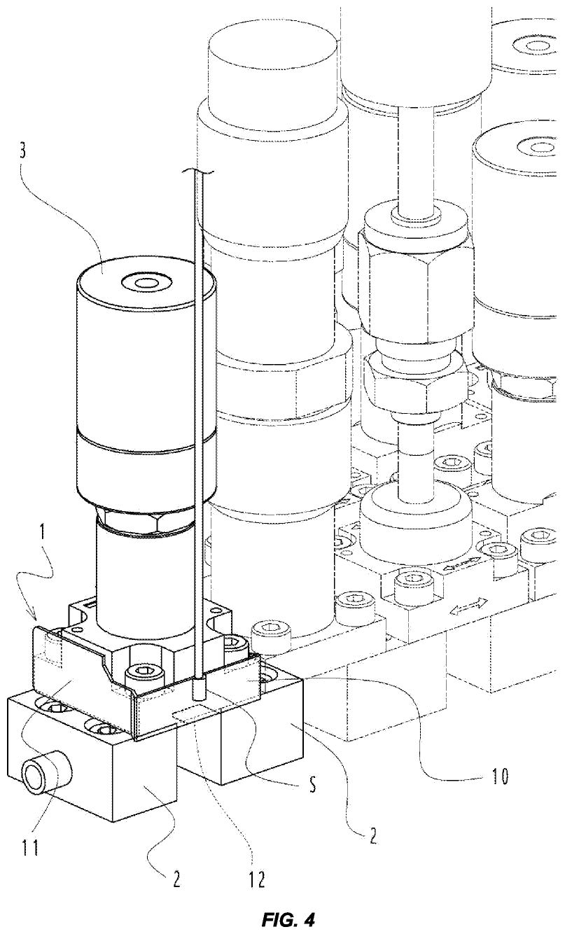

In the illustrated example, the stopper piece 12 is extended from the temperature sensor attachment piece 10, and the stopper pieces 13 are extended from the clamping pieces 11, 11, but the stopper piece may be formed at any one position. In particular, the stopper pieces 13 formed to extend from the clamping pieces 11 cannot be used when there is no gap or step between the fluid control device 3 serving as the upper block and an upper surface of the flow path block 2 serving as the lower block. Therefore, it is preferable to form only the stopper piece 12 extending from the temperature sensor attachment piece 10. By forming the stopper piece 12, as shown in FIG. 4, when the temperature sensor S is attached to the fluid control device 3 (upper block), even when an upward stress (pull-out force) is applied to the temperature sensor S, the stopper piece 12 abuts against a lower surface of the upper block, so that the temperature sensor S can be prevented from being pulled out of the flow path block.

### Third Embodiment

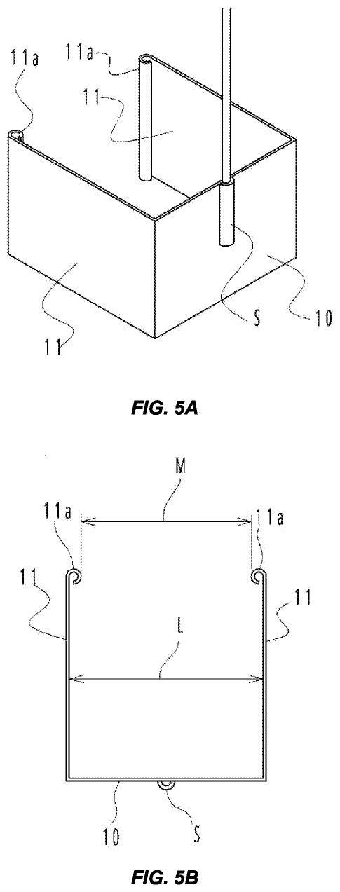

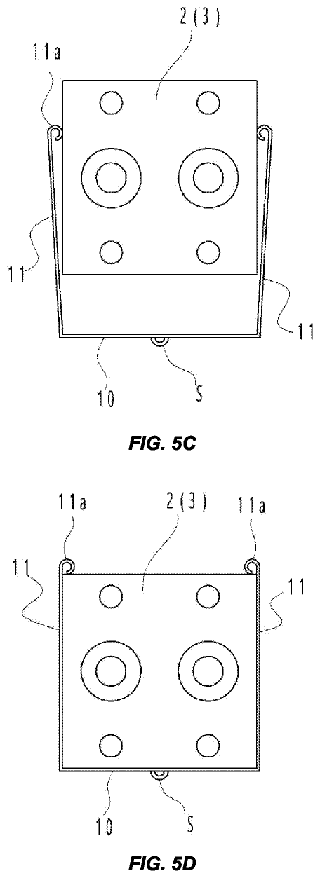

Further, in the temperature sensor attachment structure 1 shown in FIG. 5 (a), end sides of the clamping pieces 11, 11 on sides opposite to a temperature sensor attachment piece side can be protruded inward. A shape of a protruding portion is not particularly limited, but in the present embodiment, a protruding portion 11a is formed by winding the end side inward in an arc shape.

When an interval M between the protruding portions 11a, 11a is formed to be shorter than the interval L between the clamping pieces 11, 11, the shape of the protruding portion 11a may be formed by simply bending the end side.

When the temperature sensor attachment structure 1 is attached to the flow path block 2 (lower block) or the fluid control device 3 (upper block), the clamping pieces 11, 11 are expanded until the interval M between the protruding portions 11a, 11a becomes equal to a width size of the block (the interval L between the normal clamping pieces 11, 11), and the protruding portions 11a, 11a are slid while being brought into sliding contact with side surfaces of the block (see FIG. 5(c)), and when the protruding portions 11a, 11a pass through the side surfaces of the block, due to the elasticity of the clamping pieces 11, 11, the protruding portions 11a, 11a are stuck in a surface of the block facing the temperature sensor attachment piece 10, and a position of the temperature sensor S does not change and is firmly fixed even when not only an upward stress (pull-out force) but also a horizontal stress is generated.

In the present embodiment, it is needless to say that the inner sides of the opposite sides 10a can be bent at an acute angle as described in the first embodiment, or the stopper pieces 12, 13 can be formed as described in the second embodiment.

### INDUSTRIAL APPLICABILITY

As described above, since the temperature sensor attachment structure according to the invention can effectively prevent the temperature sensor attached to the integrated fluid control apparatus from being pulled out upward, it can be widely suitably used for an integrated fluid control apparatus and also suitably used for attaching a temperature sensor to the existing integrated fluid control apparatus.

### REFERENCE SIGNS LIST

1 temperature sensor attachment structure
10 temperature sensor attachment piece
11 clamping piece
12 stopper piece
13 stopper piece
2 flow path block (lower block)
3 fluid control device (upper block)
4 support member
5 clip
100 fluid control apparatus
S temperature sensor
H heating unit

1. A temperature sensor attachment structure to be attached to flow path blocks or a fluid control device of a fluid control apparatus including the plurality of flow path blocks each of which includes a fluid flow path therein and at least one surface of which has an opening portion of the fluid flow path, and the fluid control device placed on the flow path blocks, the temperature sensor attachment structure comprising:
a rectangular temperature sensor attachment piece; and
a pair of clamping pieces extending from opposite sides of the attachment piece facing each other.

2. The temperature sensor attachment structure according to claim 1, wherein
a stopper piece extends inward from a lower side of at least one of the temperature sensor attachment piece and the clamping pieces.

3. The temperature sensor attachment structure according to claim 1, wherein
bending portions that are bent inward are provided on end sides of the clamping pieces on sides opposite to a temperature sensor attachment piece side.

4. The temperature sensor attachment structure according to claim 1, wherein
a surface of the temperature sensor attachment piece is covered with a ribbon-shaped heating unit.

5. The temperature sensor attachment structure according to claim 2, wherein
bending portions that are bent inward are provided on end sides of the clamping pieces on sides opposite to a temperature sensor attachment piece side.

6. The temperature sensor attachment structure according to claim 2, wherein
a surface of the temperature sensor attachment piece is covered with a ribbon-shaped heating unit.

7. The temperature sensor attachment structure according to claim 3, wherein
a surface of the temperature sensor attachment piece is covered with a ribbon-shaped heating unit.

8. The temperature sensor attachment structure according to claim 5, wherein
a surface of the temperature sensor attachment piece is covered with a ribbon-shaped heating unit.
